(19) United States
(12) Patent Application Publication
(10) Pub. No.: US 2022/0077337 A1
(43) Pub. Date: Mar. 10, 2022

(54) COVER SHEET FOR PHOTOVOLTAIC PANEL

(71) Applicant: Loughborough University, Leicestershire (GB)

(72) Inventors: Piotr Michal Kaminski, Leicestershire (GB); Adam Michael Law, Leicestershire (GB); Lewis David Wright, Leicestershire (GB); John Michael Walls, Leicestershire (GB)

(21) Appl. No.: 17/309,804

(22) PCT Filed: Dec. 20, 2019
(86) PCT No.: PCT/GB2019/053658

§ 371 Date: Jun. 18, 2021

(30) Foreign Application Priority Data
Dec. 21, 2018 (GB) 1821095.5

(51) Int. Cl. H01L 31/048

(52) U.S. Cl. CPC H01L 31/048

(57) ABSTRACT

A cover sheet (7) for a photovoltaic panel (4), the cover sheet (7) comprising a transparent substrate (8) and a coating (9) on the substrate (8), the coating (9) being such that the cover sheet (8) is more reflective to light of a first range of wavelengths in the infrared spectrum than to a second range of wavelengths in the visible spectrum; in which the coating (9) comprises alternating layers of first (11, 13) and second (12, 14) materials, with the first material (11, 13) having a higher refractive index than the second material (12, 14) and being a transparent conducting oxide such as indium tin oxide (ITO). Methods of manufacture including annealing the first material and/or depositing it at elevated temperatures are also discussed.

This invention relates to a cover sheet for a photovoltaic panel, a photovoltaic module using such a panel, and a use of that panel, as well as methods of manufacture of such cover sheets.

Photovoltaic (PV) panels are well known as a means for converting incident light—typically sunlight—into electrical power. Remarkable progress in the development of photovoltaic modules has been made in recent years leading to substantial cost reductions. Solar is now achieving ‘grid parity’ costs of energy generation in many parts of the world. PV is forecasted to make an important contribution to the mitigation of the world's growing energy problem. The global supply of PV modules has increased from 6 GWp (peak Gigawatt) in 2009 to 95 GWp in 2017 and 115 GW in 2018. A total of 400 GWp of solar power capacity was generating electricity worldwide at the end of 2017 (500 GW in 2018); this was sufficient to deliver almost 2% of the world energy needs.

The PV landscape is dominated by crystalline Silicon (c-Si) PV with over 90% of module production in 2017 and 2018. However, c-Si modules suffer serious losses as the operating temperature increases. Typically, these losses equate to 0.25% degradation in efficiency for each 1° C. rise in temperature. For example, at 70° C., the module efficiency will be 12.5% lower than that measured under standard test conditions at 25° C. Module temperatures of 70° C. are often reached in the United Kingdom and easily exceeded in hotter climates closer to the equator. Eliminating these losses would dramatically increase the energy output from solar panels.

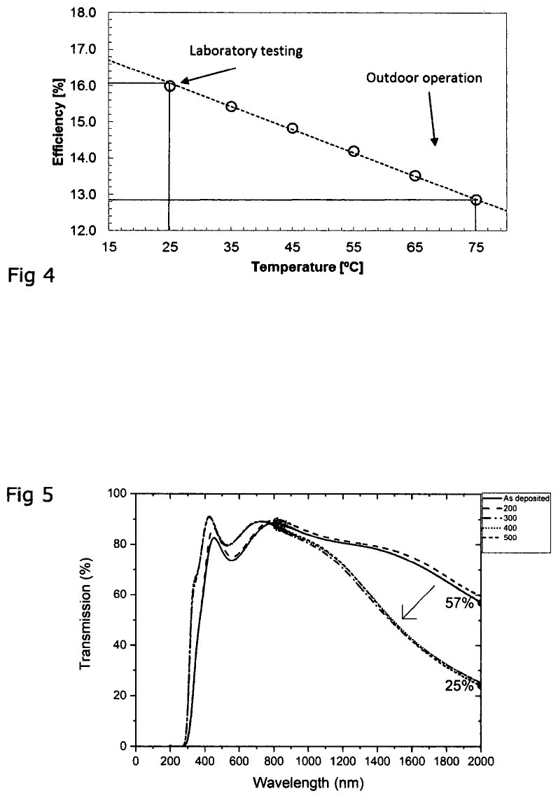

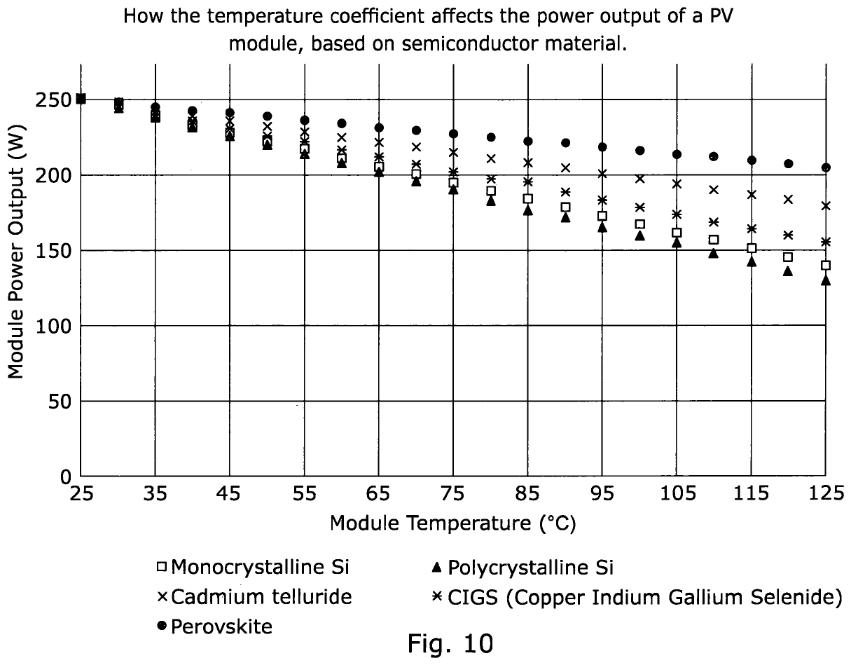

The problem is common for all PV technologies, and is measured by the temperature efficiency coefficient expressed in %/° C. efficiency loss. These losses are the result of intrinsic semiconductor properties and there is no simple way to mitigate them. FIG. 4 of the accompanying drawings shows the reduction in efficiency of a crystalline silicon module as a function of increasing temperature. The data is plotted for a device with a typical thermal efficiency coefficient of 0.25%/° C. Furthermore, FIG. 10 of the accompanying drawings shows how the efficiency of a nominal 25 W PV module of differing technologies drops with increasing temperature. All efficiency figures for PV panels are measured at 25° C.

Since the temperature coefficient is intrinsic to semiconductor behaviour, the problem cannot be addressed by modifying the module material. Limiting the temperature increase during operation would be a solution to the problem. Although active cooling using a re-circulating water cooling system would work, active cooling would be costly and complex.

According to a first aspect of the invention, we provide a cover sheet for a photovoltaic panel the cover sheet comprising a transparent substrate and a coating on the substrate, the coating being such that the cover sheet is more reflective to light of a first range of wavelengths in the infrared spectrum than to a second range of wavelengths in the visible spectrum.

As such, this coating will preferentially reflect infrared radiation (which would otherwise deleteriously heat the photovoltaic panel) but will promote the passage of visible light, which will usefully be transmitted to the photovoltaic panel for conversion to electrical energy.

Semi-transparent IR reflecting coatings on glass are already used in a number of applications such as buildings, automotive and ovens. Coatings used to reflect infrared radiation are typically based on thin layers of silver. Multiple (2-3) 5 nm thick layers of Ag are used to produce semi-transparent colour-neutral infrared reflectors. However, these coatings introduce absorption losses which make them unsuitable for the PV application.

Typically, the coating is such that the cover sheet is more reflective to light of the first range of wavelengths than if the coating were not present. Likewise, typically, the coating is such that the cover sheet is less reflective to light of the second range of wavelengths than if the coating were not present. Thus, the coating is anti-reflective to the second range of wavelengths, but more reflective to light of the first range of wavelengths.

In one embodiment, the coating may comprise alternating layers of first and second materials, with the first material having a higher refractive index than the second material. Typically, the coating will be arranged such that a layer of the first material is formed on top of the substrate. The first material may be a transparent conducting oxide, such as Indium Tin Oxide (ITO). Typically, the second material will be silica (silicon dioxide), as that is cheap and durable. The coating may consist of two layers each of the first and second materials (so four layers in total), or alternatively three layers each of the first and second materials (so six layers in total), or more.

The advantage of the multilayer approach is coating design tunability, high performance and durability. The coating does not require a thin film material with a refractive index significantly lower than glass. Hard and durable materials such as silica can be used, particularly for the second material. Multilayer coatings using such materials have proven stability in a number of environmental tests including IEC accelerated lifetime testing for PV, abrasion resistance, acid attack, in each case showing no degradation.

A multilayer anti-reflection coating (MAR) utilizes light interference to control the reflection. The interference occurs due to the change of refractive index at a medium boundary. As a result of a change of medium, part of the energy is reflected and some is transmitted. The amplitude of the transmitted and the reflected waves can be calculated using Fresnel equations. MAR coatings, based on a thin film multilayer design, utilize destructive interference at medium boundaries to reduce the reflection.

Multilayer optical coatings achieve high performance anti-reflection by maximizing the contrast between the high refractive index layers and the low refractive index layers. Reflection of the first range in such a coating can be achieved by using a material with dynamic changes of the refractive index in the IR region. Transparent Conductive Oxides (TCO) have the required properties due to presence of free electrons. Indium Tin Oxide (ITO) has a refractive index of approximately 2 at 550 nm in the visible spectrum. It has a zero extinction coefficient in the second wavelength range in the visible part of the spectrum and the required change in the second range in the IR spectrum. It is possible to make coatings using TCO layers in many fewer layers than if other materials are chosen.

These properties make such materials suitable for the coating. The high value of the refractive index in the visible spectrum enables the coating to reduce reflection from the front surface of the glass. The lower refractive index in the Infra-red region enables the coating to reflect the IR photons.

In one example, the coating would comprise or consist of:
a) a first layer of first material on the substrate, having a thickness of 18.6 nm±a tolerance;
b) a second layer of second material on the first layer, having a thickness of 25.2 nm±a tolerance;
c) a third layer of first material on the second layer, having a thickness of 142.7 nm±a tolerance; and
d) a fourth layer of second material on the third layer, having a thickness of 87.9 nm±a tolerance;
   in which the tolerance on each of the first, second, third and fourth layers is 2%, 1.5% or 1% of the thickness of the respective layer, or 2 nm or 1 nm.

This arrangement has been found to be particularly efficient at reflecting infrared light but transmitting visible light.

Typically, the photovoltaic panel will have an operating range of wavelengths which it will convert to electrical energy; the operating range may be limited at a longer wavelength end by an absorption edge of the photovoltaic panel. Typically, the second range will contain the operating range, or a majority of the operating range. Typically, there will be no overlap between the first range and the operating range.

The first range may be, or may comprise a range from a first value to a second value. The second value may be any of 1150 nm, 1200 nm, 1300 nm or 1400 nm. The second value may be any of 2750 nm, 2800 nm, 2900 nm, 3000 nm or 4000 nm.

The second range may be, or may comprise a range from a first value to a second value. The second value may be any of 300 nm, 325 nm or 350 nm (the latter value being the absorption edge for glass). The second value may be any of 800 nm, 900 nm, 1000 nm or 1150 nm.

The reflectance over the first range may be a maximum of 3%, 2%, 1.75% or 1.5%. The reflectance over the second range may be at least 20%, 30%, 40%, 50% or 60%. The substrate may be glass, typically soda lime glass. Alternatively, it can be a transparent polymer material, such as a polycarbonate.

In one embodiment, the cover sheet may be separate from the photovoltaic panel. Alternatively, the cover sheet may be integral with the photovoltaic panel, which may comprise an active surface formed on the substrate, typically on the opposite side of the substrate to the coating.

According to a second aspect of the invention, there is provided a photovoltaic module, comprising a photovoltaic panel having an active surface such that light incident on the active surface is converted by the photovoltaic panel to electrical energy, and a cover sheet shielding the active surface, in which the cover sheet is in accordance with the first aspect of the invention.

In one embodiment, the cover sheet may be separate from the photovoltaic panel. There may be a space between the cover sheet and the photovoltaic panel, which may be filled with a transparent filler, such as a transparent polymer filler, such as ethyl-vinyl acetate (EVA). This is typically the case with crystalline Silicon (c-Si) photovoltaic panels.

In another embodiment, the cover sheet may be integral with the photovoltaic panel, and the active substrate may be formed on the substrate, typically on the opposite side of the substrate to the coating. This is typically the case with thin film cadmium telluride (CdTe) photovoltaic panels.

The module may further comprise a housing arranged to contain the photovoltaic panel and having an aperture, in which the cover sheet seals the aperture.

In either of the preceding aspects, the photovoltaic panel may be a crystalline Silicon (c-Si), copper indium gallium di-selenide (CIGS) or a cadmium telluride (CdTe) photovoltaic panel, or any other suitable panel, especially one whose efficiency decreases with increasing temperature.

According to a third aspect of the invention, there is provided the use of a cover sheet in accordance with the first aspect of the invention to reduce reflections in the second range of wavelengths and to reflect light in the first range of wavelengths.

According to a fourth aspect of the invention, there is provided a method of making a cover sheet in accordance with the first aspect of the invention, the method comprising depositing the alternating layers of the first and second materials on the substrate and annealing the deposited layers.

Annealing the layers has been found to improve the transmission and reflectance performance in the manner desired (that is, potentially more transmittance and less reflectance in the visible spectrum, and more reflectance and less transmittance in the infra-red spectrum). It provides an even more favourable refractive index dispersion in the transparent conductive oxide (typically indium tin oxide).

Typically, the layers will be annealed after all of the layers have been deposited. The annealing may take place at at least 250° C. or 300° C., or 400° C., or 500° C. The depositing of the layers may take place at less than 50° C., 30°, 25° C. or 20° C.

According to a fifth aspect of the invention, there is provided a method of making a cover sheet in accordance with the first aspect of the invention, the method comprising depositing the alternating layers of the first and second materials on the substrate, with the deposition of the layers of the first material occurring at a temperature of at least 250° C.

Depositing at least the layers of first material at an elevated temperature has been found to improve the transmission and reflectance performance in the manner desired (that is, potentially more transmittance and less reflectance in the visible spectrum, and more reflectance and less transmittance in the infra-red spectrum).

The deposition of the layers of second material may also occur at a temperature of above 250° C. The temperature at which the layers of first and/or second materials are deposited may be at least 300° C., or 400° C., or 500° C.

The method may comprise the step of heating the substrate to the temperature of at least 250° C.

There now follows, by way of example, description of an embodiment of the invention, in which:

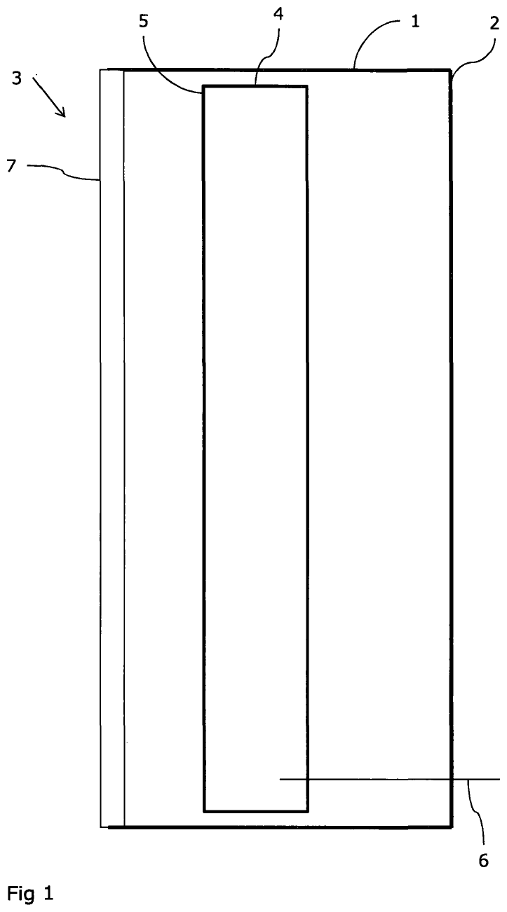

FIG. 1 shows a schematic view of a photovoltaic module in accordance with an embodiment of the invention;

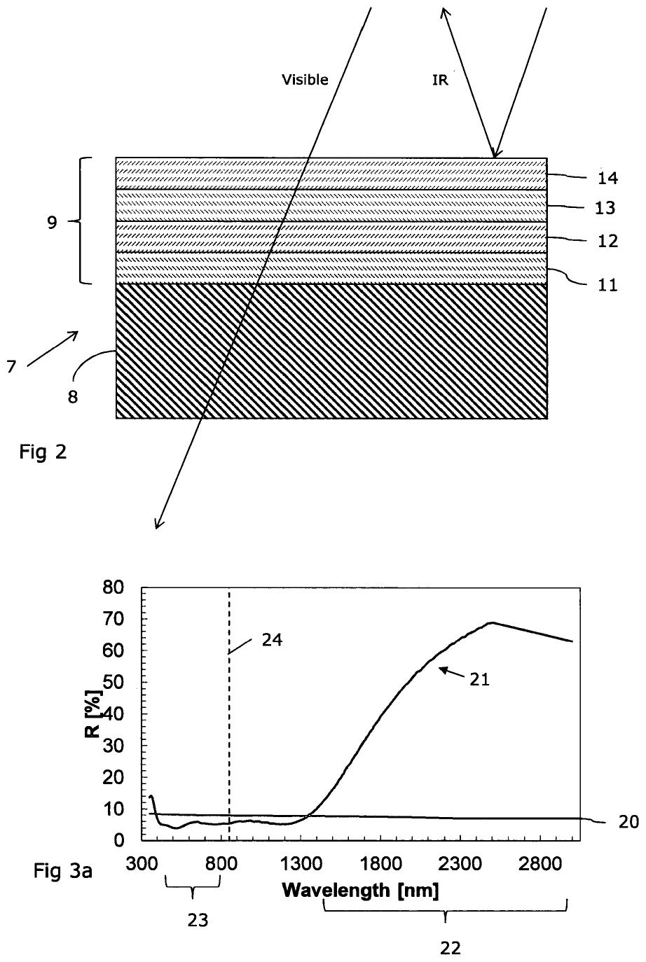

FIG. 2 shows a cross section through the cover glass of the module of FIG. 1;

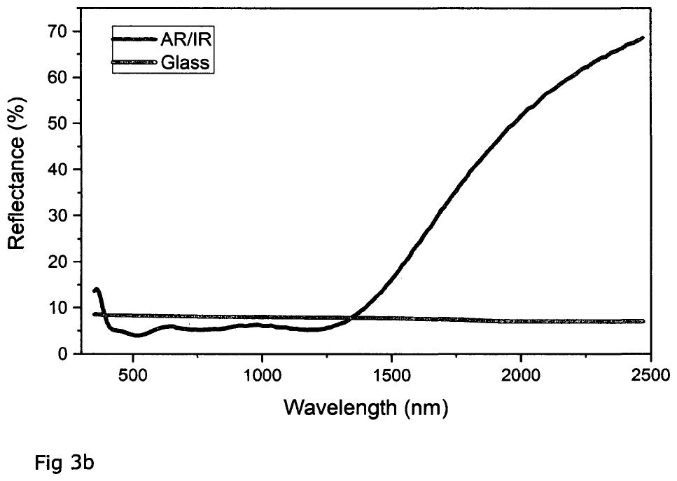

FIG. 3a shows a graph of the reflection of the cover glass of FIG. 2 at differing wavelengths;

FIG. 3b shows a corrected graph of the reflection of the cover glass of FIG. 2 at differing wavelengths;

FIG. 4 shows a graph of PV panel efficiency with operating temperature;

FIG. 5 shows a graph of transmission against wavelength for a layer of Indium Tin Oxide on glass before and after annealing;

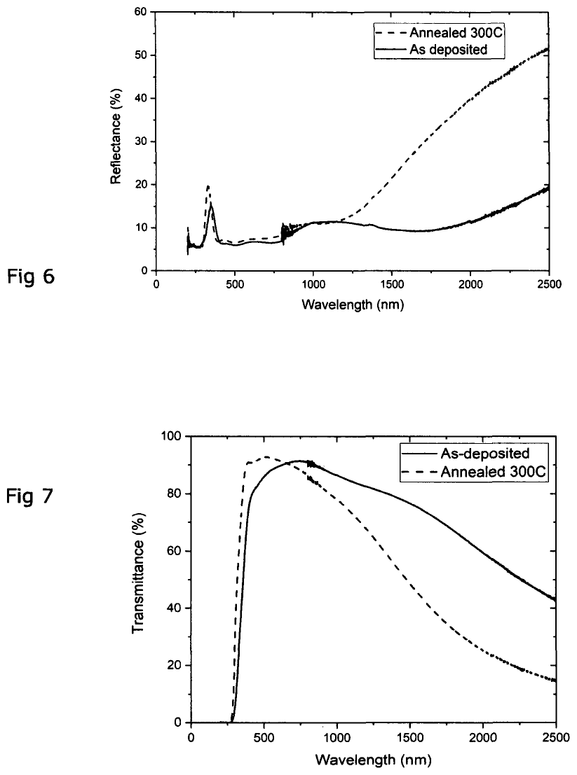

FIGS. 6 and 7 show graphs of reflectance and transmittance respectively as against wavelength for an example cover glass before and after annealing;

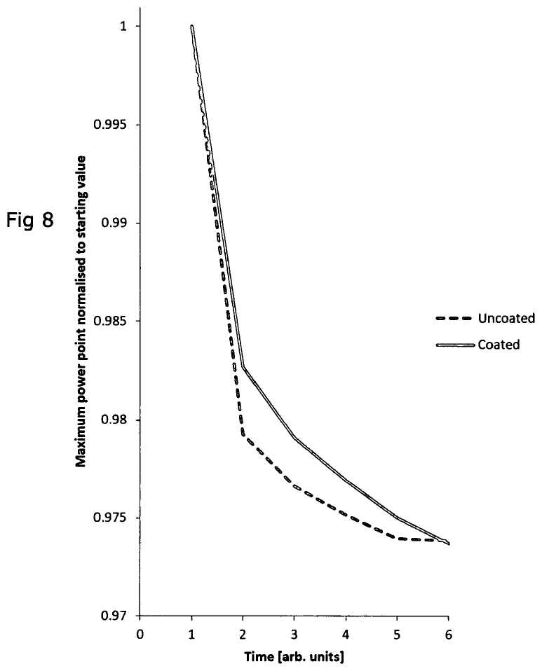

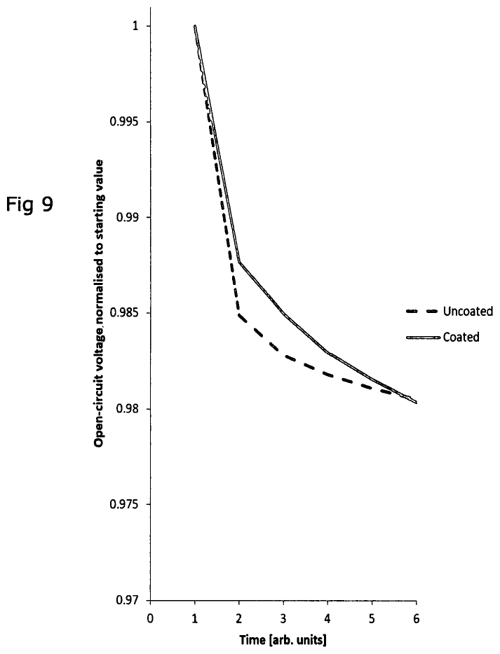

FIGS. 8 and 9 show graphs of the power and open circuit voltage output with time by a photovoltaic cell under the cover glass of FIG. 6; and

FIG. 10 shows a graph of the power output of PV modules with increasing temperature.

A photovoltaic module 1 in accordance with an embodiment of the invention is shown in FIG. 1 of the accompanying drawings. It comprises a housing 2 which is open on one face 3. The housing contains a photovoltaic panel 4 which is arranged to convert light incident on its front face 5 into electrical power, which can be transmitted elsewhere through electrical connections 6.

In order to protect the panel 4 against the physical environment, a cover glass sheet 7 is provided. This not only protects the panel 4 against environmental intrusion, but acts as explained below to preferentially reflect infrared radiation away from the panel 4, whilst reducing the reflection of useful visible light.

The cover glass 7 can be seen in more detail in FIG. 2 of the accompanying drawings; the thicknesses of the layers have been greatly distorted for ease of description. The cover glass 7 is shown in FIG. 2 such that the face shown bottommost would face the panel 4 and the topmost face shown would face the outside world, and the source of illumination (typically the sun).

The cover glass 7 comprises a glass substrate 8 which can be as thick as required for the physical properties—in particular the physical strength—of the cover glass 7. Typically, the glass substrate 8 would be formed of toughened soda lime glass and would be approximately 3 mm thick.

The cover glass 7 has a coating 9 on its top face (facing away from the panel 4). The coating is reflective to light of a first range of wavelengths largely in the infrared, and reduces reflections—that is anti-reflective—in a second range of wavelengths largely in the visible spectrum.

The coating comprises four layers, working upwards from the substrate:
a) a first layer 11 of Indium Tin Oxide (ITO) (refractive index 2.13) on the substrate 8, having a thickness of approximately 18.6 nm;
b) a second layer 12 of silica (SiO₂) (refractive index 1.45) on the first layer 11, having a thickness of approximately 25.2 nm;
c) a third layer 13 of ITO on the second layer 12, having a thickness of approximately 142.7 nm; and
d) a fourth layer 14 of silica on the third layer 13, having a thickness of approximately 87.9 nm.

The thickness of the layers is selected such that, over the first range, the layers of differing refractive index interact with incident light to promote reflection through interference, whereas the opposite occurs—reduction of reflection—in the second range. The optical coatings were designed using the “Essential Macleod” optical modelling software package. The software models the performance of an optical coating by considering propagation of electromagnetic wave using the transfer matrix method.

In this embodiment, Indium Tin Oxide (ITO) was chosen as the high refractive index material, with silica (SiO₂) chosen as the low index material.

This can be seen in the simulated behaviour shown in FIG. 3a of the accompanying drawings. The photo-generated current was estimated based on the transmission of light through the coating. The AM1.5 g solar spectrum was used at 1000 W/m². For simplicity, internal quantum efficiency (IQE) of 100% has been assumed. The temperature increase of the PV module during operation was calculated for the energy mismatch between the bandgap and the photon energy and that due to absorption of the Infra-red photons. The bandgap of the absorber was used to define the two spectra (division at 1150 nm). This enables an easy estimation of the coating performance.

A corrected version of the data shown in FIG. 3a is shown in FIG. 3b, removing a potentially incorrect linear extrapolation of the data above 2500 nm.

In this Figure, trace 20 shows the reflectance of the cover glass sheet 7 without the coating 9, whilst trace 21 shows the reflectance of the cover glass 7 with the coating 9. As such, it can be seen for a first range of wavelengths 22 in the infrared spectrum (from approximately 1500 to 3000 nm) the reflectance with the coating 9 is higher than without. In a second range of wavelengths 23 (from approximately 350 to 1150 nm) the reflectance is lower with the coating 9 than without; the design of the coating was optimized to minimize the reflection losses for the second range. It can be seen that the second range is below the absorption edge 24 of the panel 4 (that for a Cadmium Telluride (CdTe) panel shown), whereas the first range is above.

As such, the coating 9 reduces the reflection in the operating range of a crystalline silicon (c-Si) photovoltaic (PV) module. The reflection from the front (top) surface of the cover glass 7 is reduced from 4.5% to below 1% in the 350 nm to 1150 nm wavelength range. Increased reflection for the longer wavelengths is observed. The increased reflectance is a consequence of the interference induced by the coating design and reaches as high as 70%.

The coating 9 reduces the weighted average reflection (WAR) in the second, useful wavelength region down to 1.24% from 4.22%. For this value of WAR (1.24%) the maximum attainable current is increased to 44.36 mA/cm² from 43.02 mA/cm². The use of ITO improves the antireflective performance of the coating as well as adding the benefit of reflecting the Infra-red first range.

Modelling the temperature increase of a solar cell under 1000 W/cm² AM1.5 (a standard for PV illumination) illumination showed that the temperature of a cell increases by 15.7° C. due to absorption of sub-bandgap photons alone without the coating 9. For a solar cell with cover glass applied with the coating 9, the temperature increase due to IR photons is reduced to 10.1° C. This achieves over 35% reduction in the temperature increase due to IR radiation.

The total temperature increase in this scenario was 26.8° C. without the coating 9 compared with 21.2° C. with the coating 9. This is a 20% reduction on the total temperature increase due to energy mismatch and sub-bandgap photons.

An example cover glass in accordance with the above embodiment has been manufactured. The coatings were deposited on a silica glass substrate via pulsed-DC magnetron sputtering using silicon and ITO targets. The silicon layers are deposited via reactive sputtering, where the sputtered material is pure silicon, which then passes through an oxygen-rich plasma to form an oxide layer. The ITO layers are deposited from a compound target.

The layers were as follows:

| Layer | Material | Thickness (nm) |
|---|---|---|
| 1 | SiO₂ | 88 |
| 2 | ITO | 143 |
| 3 | SiO₂ | 25 |
| 4 | ITO | 19 |
| Substrate | Glass | n/a |

During manufacture, it was appreciated that annealing the layers can provide performance improvements. FIG. 5 shows the transmittance of a single ITO layer (layer 4 in the table above) on the glass substrate before and after annealing at different temperatures. It can be seen that the transmittance in the high wavelength IR range decreases (desirably) when the ITO layer is annealed at a temperature of at least 300° C. As such, we have found that the ITO can be deposited at room temperature, and then subsequently annealed at at least 300° C. (which is in itself a not especially high temperature, which would require only moderate energy use to heat the stack to such a temperature).

We have also appreciated that the whole stack can be deposited at room temperature and then subsequently annealed. FIGS. 6 and 7 show the reflectance and transmittance of the whole stack as set out in the table above before and after annealing at 300° C. for an hour. It can be seen that the reflectance in the IR range is higher than in the visible spectrum, and that the transmittance is higher in the visible range and lower in the IR range as is desired in this invention, using only four layers.

An uncoated sample and the coated sample discussed above were measured under simulated light every 15 seconds for 15 minutes. The graphs below show normalised open-circuit voltage (Voc) and maximum power point (MPP).

The rate of Voc reduction of the coated sample is lower than uncoated. The change in rate shows the intended effect is nonetheless achieved, successfully reproducing theoretical predictions.

In alternatives, the deposition of the layers could take place at elevated temperatures (300° C. or above) and/or the substrate could be heated to 300° C. or above to achieve the advantages described above for annealing.

As such, this embodiment combines the benefits of a reduction in reflections in the second, useful, wavelength range, increasing the efficiency in which the PV module 1 can convert the incident light to electrical power, with the reflection of infrared radiation that only contributes to heating the PV panel 4, thus increasing the efficiency of the PV panel by at least partially ameliorating any temperature increase.

Whilst we have proposed the use of ITO as the material of higher refractive index, it is possible to use other transparent conductive oxides; it is a matter of varying the thicknesses of the alternating layers, typically using a computer model, until the desired reflective and anti-reflective behaviours are achieved.

Modules suffer significant performance losses as the temperature of the modules increase. Previous designs of broadband multilayer anti-reflection coatings using alternate high and low refractive index have been shown to offer high efficiency gains. Their durability has been tested and proven making them a suitable solution for high volume manufacturing.

Combining a multilayer anti-reflection coating with an infra-red reflector is a new concept for module temperature reduction. Avoiding the use of silver for the infra-red reflection means that the optical transmission is not compromised.

Calculations show that the new type of optical coating can reduce the temperature increase caused by sub-bandgap photons by >35%. Adoption of the coating on solar cover glass increases the amount of energy produced by a PV module.

Decreasing the working temperature of the panels will have the added benefit of increasing PV lifetime as the temperature plays important role in degradation. This will further reduce the cost of PV electricity.

The Infra-red reflecting optical coating is a technology agnostic solution. The efficiency gains are proportional to the device efficiency. The higher the efficiency of the PV module, the higher the energy gains obtained by coating the cover glass. The coating also acts as an Anti-Reflection coating in the wavelengths absorbed by the solar module. This effect increases the module efficiency by reducing reflection losses from 4.22% to 1.24%. The benefits of a cover glass coating which combines anti-reflection with reduced module temperature will have a dramatic effect of the efficiency of solar installations and an associated reduction in the cost of electricity produced. The incorporation of a transparent conductor (such as ITO) will also introduce an anti-static function, so that the cover sheet will not attract as much dust to the surface, preventing losses due to surface soiling.

1. A cover sheet for a photovoltaic panel the cover sheet comprising a transparent substrate and a coating on the substrate, the coating being such that the cover sheet is more reflective to light of a first range of wavelengths in the infrared spectrum than to a second range of wavelengths in the visible spectrum,
wherein the coating comprises alternating layers of first and second materials, with the first material having a higher refractive index than the second material and being a transparent conducting oxide.

2. The cover sheet of claim 1, in which the coating is such that the cover sheet is more reflective to light of the first range of wavelengths than if the coating were not present.

3. The cover sheet of claim 1, in which the coating is such that the cover sheet is less reflective to light of the second range of wavelengths than if the coating were not present.

4. The cover sheet of claim 1, in which the coating is arranged such that a layer of the first material is formed on top of the substrate.

5. The cover sheet of claim 1, in which the first material is indium tin oxide (ITO).

6. The cover sheet of claim 1, in which the second material is silica (silicon dioxide).

7. The cover sheet of claim 1, in which the coating consists of two layers each of the first and second materials.

8. The cover sheet of claim 1, in which the coating comprises:
a) a first layer of indium tin oxide on the substrate, having a thickness of 18.6 nm±a tolerance;
b) a second layer of silica on the first layer, having a thickness of 25.2 nm±a tolerance;
c) a third layer of indium tin oxide on the second layer, having a thickness of 142.7 nm±a tolerance; and
d) a fourth layer of silica on the third layer, having a thickness of 87.9 nm±a tolerance,
wherein the tolerance on each of the first, second, third and fourth layers is 2%, 1.5% or 1% of the thickness of the respective layer, or 2 nm or 1 nm.

9. The cover sheet of claim 1, wherein the photovoltaic panel has an operating range of wavelengths within which light is converted to electrical energy, with the operating range being limited at a longer wavelength end by an absorption edge of the photovoltaic panel,
wherein the second range contains the operating range, or a majority of the operating range.

10. The cover sheet of claim 9, in which there is no overlap between the first range and the operating range.

11. A photovoltaic module, comprising a photovoltaic panel having an active surface such that light incident on the active surface is converted by the photovoltaic panel to electrical energy, and the cover sheet according to claim 1 shielding the active surface.

12. The photovoltaic module of claim 11, further comprising a housing arranged to contain the photovoltaic panel and having an aperture, in which the cover sheet seals the aperture.

13. A method of using the cover sheet of claim 1, the method comprising reducing reflections in the second range of wavelengths and reflecting light in the first range of wavelengths.

14. A method of making a cover sheet comprising a transparent substrate and a coating on the substrate, the coating being such that the cover sheet is more reflective to light of a first range of wavelengths in the infrared spectrum than to a second range of wavelengths in the visible spectrum,
wherein the coating comprises alternating layers of first and second materials, with the first material having a higher refractive index than the second material and being a transparent conducting oxide, the method comprising depositing the alternating layers of the first and second materials on the substrate and annealing the deposited layers.

15. The method of claim 14, in which the layers are annealed after all of the layers have been deposited.

16. The method of claim 14, in which the annealing takes place at at least 250° C.

17. The method of claim 14, in which the depositing of the layers takes place at less than 50° C.

18. A method of making a cover sheet comprising a transparent substrate and a coating on the substrate, the coating being such that the cover sheet is more reflective to light of a first range of wavelengths in the infrared spectrum than to a second range of wavelengths in the visible spectrum,
wherein the coating comprises alternating layers of first and second materials, with the first material having a higher refractive index than the second material and being a transparent conducting oxide, the method comprising depositing the alternating layers of the first and second materials on the substrate, with the deposition of the layers of the first material occurring at a temperature of at least 250° C.

19. The method of claim 18, in which the deposition of the layers of second material also occurs at a temperature of above 250° C.

20. The method of claim 18, further comprising heating the substrate to the temperature of at least 250° C.
